(19) United States
(12) Patent Application Publication
(10) Pub. No.: US 2007/0096285 A1
(43) Pub. Date: May 3, 2007

(54) Semiconductor die package including construction for preventing delamination and/or cracking of the semiconductor die

(76) Inventors: Chin-Tien Chiu, Taichung City (TW); Jack Chang Chien, Kaoshiung City (TW); Meng-Ju Tsai, Kaohsiung (TW); Cheemen Yu, Madison, WI (US); Hem Takiar, Fremont, CA (US)

Correspondence Address: VIERRA MAGEN/SANDISK CORPORATION, 575 MARKET STREET, SUITE 2500, SAN FRANCISCO, CA, 94105, US

(21) Appl. No.: 11/265,336

(22) Filed: Nov. 2, 2005

(51) Int. Cl. H01L 23/02

(52) U.S. Cl. 257/686

(57) ABSTRACT

A semiconductor die substrate is disclosed for preventing delamination of the die and/or die cracking due to air bubbles trapped beneath the die, and a semiconductor package incorporating the substrate. A solder mask may be laminated on a surface of the substrate which is patterned with one or more passageways, or canals, allowing air bubbles to be expelled from beneath the semiconductor die during the semiconductor package fabrication. The canals may have a variety of shapes, including for example a wavy, undulating shape.

### BACKGROUND OF THE INVENTION

1. Field of the Invention

Embodiments of the present invention relate to a semiconductor die substrate for preventing delamination of the die and/or die cracking, and a semiconductor package incorporating the substrate.

2. Description of the Related Art

The strong growth in demand for portable consumer electronics is driving the need for high-capacity storage devices. Non-volatile semiconductor memory devices, such as flash memory storage cards, are becoming widely used to meet the ever-growing demands on digital information storage and exchange. Their portability, versatility and rugged design, along with their high reliability and large capacity, have made such memory devices ideal for use in a wide variety of electronic devices, including for example digital cameras, digital music players, video game consoles, PDAs and cellular telephones.

While a wide variety of packaging configurations are known, flash memory storage cards may in general be fabricated as system-in-a-package (SiP) or multichip modules (MCM), where a plurality of die are mounted on a substrate. The substrate may in general include a rigid, dielectric base having a conductive layer etched on one or both sides. Electrical connections are formed between the die and the conductive layer(s), and the conductive layer(s) provide an electric lead structure for communication between the die and an external electronic system. Once electrical connections between the die and substrate are made, the assembly is then typically encased in a molding compound to form a protected semiconductor package.

A cross-section of a conventional semiconductor package 20 is shown in FIG. 1. The substrate 22 in general is formed of a rigid core 26, of for example polyimide laminate. Thin film conductive layers 28 may be formed on the core in a desired conductance pattern using known photolithography and etching processes. The substrate 22 may then be coated with a solder mask 34 to insulate and protect the electrical lead pattern defined on the substrate. After the substrate is formed, one or more die 36 are mounted on the substrate 22 via die attach film 24. Die attach film 24 adheres the die to the substrate and also laminates the substrate. The die may then be electrically connected to the substrate by wire bonds 32. Where package 20 comprises a land grid array (“LGA”) package, gold bond pads 38 may further be formed on a bottom surface of the package for communication with external devices. Further examples of typical semiconductor packages are disclosed in U.S. Pat. Nos. 4,684,184, 5,199,889 and 5,232,372, which patents are incorporated by reference herein in their entirety.

The upper surface of the substrate 22 is not flat. As a result of the etched conductance pattern in the conductive layer 28, the portions of the substrate where the conductive layer 28 remains has a greater thickness than the gaps between conductive traces where the layer 28 has been etched away. Moreover, openings and small imperfections in the conductive layer 28 and/or core layer 26 can also result in an uneven surface of the substrate. Thus, when the solder mask 34 is coated onto the substrate, the upper surface of the solder mask 34 similarly is not flat.

When the die is mounted to the solder mask layer with the die attach film, the film is generally an uncured, relatively viscous liquid, and does not adhere to all of the small valleys on the uneven surface of the solder mask 34. As a result, tiny air bubbles get trapped in the spaces where the die attach film does not adhere to the solder mask. Although small when initially trapped, these air bubbles tend to expand when the package is heated, as during the encapsulation process.

These expanding air bubbles present at least two problems. First, the die may delaminate from the substrate if enough of these air bubbles develop. Second, the die are subjected to large forces during the encapsulation process. The molding machine may output an injection force typically about 0.8 tons to drive the molding compound into the mold cavity. For die having a footprint of about 4.5 mm by 2.5 mm, this injection force may result in a pressure down on the die of about 1.2 kgf/mm². The uneven surface below the die resulting from the air bubbles may cause deformation of the die. This deformation can cause fractures in the die, known as die cracking.

In the past, the thickness of the die was such that delamination of the die could be cured by increasing the molding pressure to reduce the delaminated area. Moreover, the thicker die were sturdier and much less prone to die cracking. However, chip scale packages (“CSP”) and the constant drive toward smaller form factor packages require very thin die. It is presently known to employ wafer backgrind during the semiconductor fabrication process to thin die to a range of about 2 mils to 13 mils. At these thicknesses, the die are often not able to withstand the stress concentrations generated during the molding process. Similarly, the prior solution of increasing molding pressure to reduce delamination is generally no longer an option. Thus, as the thicknesses of the die continue to decrease, the problems presented by trapped air bubbles are becoming more significant.

### SUMMARY OF THE INVENTION

Embodiments of the invention relate to a semiconductor die substrate for preventing delamination of the die and/or die cracking, and a semiconductor package incorporating the substrate. The semiconductor die package may be formed of a substrate including conductance patterns formed on its top and/or bottom surface. One or more semiconductor die may be mounted on a first surface of a substrate, and a molding compound may then be provided for encapsulating the one or more semiconductor die and substrate.

Before the die are mounted on the substrate, a solder mask may be laminated on the first surface of the substrate to prevent the solder from sticking to any metallization except where openings are patterned into the solder mask. In accordance with embodiments of the invention, the solder mask may be patterned with one or more passageways, or canals. The canals may have a wavy, undulating shape, but a variety of different shapes are contemplated.

When the semiconductor die are mounted to the solder mask with a die attach film, at least a portion of the one or more canals are positioned beneath the semiconductor die. In embodiments, the canals may extend beneath the semiconductor die in a direction generally parallel to a direction of flow of the molding compound as the compound encapsulates the die. As air bubbles develop and/or expand, for example during the molding process, the air bubbles may be expelled from the beneath the semiconductor die through the one or more canals. Thus, the problem of delamination and/or die cracking due to the formation and expansion of trapped air bubbles may be significantly reduced or avoided altogether.

### BRIEF DESCRIPTION OF THE DRAWINGS

FIG. 1 is a prior art cross-sectional view of semiconductor die mounted on a substrate.

FIG. 2 is a top view of a solder mask layer applied to a substrate and patterned according to embodiments of the present invention.

FIG. 3 is a cross-sectional view through line 3-3 in FIG. 2.

FIG. 4 is a top view of a substrate including a patterned solder mask according to embodiments of the present invention having a semiconductor die mounted thereon.

FIG. 5 is a cross-sectional view through line 5-5 in FIG. 4.

FIG. 6 is a cross-sectional view of a completed semiconductor package including a patterned solder mask according to embodiments of the present invention.

FIGS. 7-10 are top views of a patterned solder mask according to alternative embodiments of the present invention.

FIG. 11 is a flowchart of a process for forming a conductance pattern on a substrate according to the present invention.

FIG. 12 is a flowchart illustrating the manufacturing process of a semiconductor package according to the present invention.

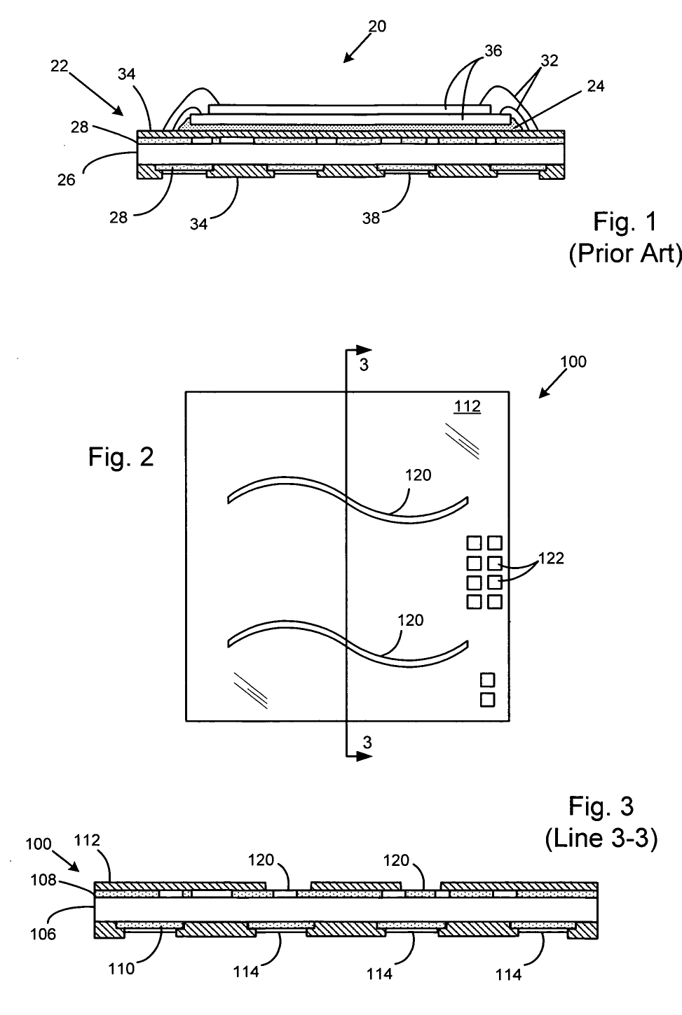

### DETAILED DESCRIPTION

Embodiments of the invention will now be described with reference to FIGS. 2 through 12, which relate to a semiconductor die substrate for preventing delamination of the die from the substrate and/or die cracking, as well as a semiconductor package incorporating the substrate. It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

Referring initially to the top and cross-sectional views of FIGS. 2 and 3, there is shown a substrate 100 including a solder mask layer 112 patterned to prevent delamination and/or cracking of semiconductor die mounted on the substrate as explained hereinafter. Substrate 100 may be formed of a core 106, having a top conductive layer 108 formed on a top surface of the core 106, and a bottom conductive layer 110 formed on the bottom surface of the core 106. The core 106 may be formed of various dielectric materials such as for example, polyimide laminates, epoxy resins including FR4 and FR5, bismaleimide triazine (BT), and the like. Although not critical to the present invention, core 106 may have a thickness of between 40 microns (μm) to 200 μm, although thickness of the core may vary outside of that range in alternative embodiments. The core 106 may be ceramic or organic in alternative embodiments.

The conductive layers 108 and 110 may be formed of copper or copper alloys, plated copper or plated copper alloys, Alloy 42 (42Fe/58Ni), copper plated steel, or other metals and materials known for use on substrates. The layers 108 and 110 may have a thickness of about 10 μm to 24 μm, although the thickness of the layers 108 and 110 may vary outside of that range in alternative embodiments.

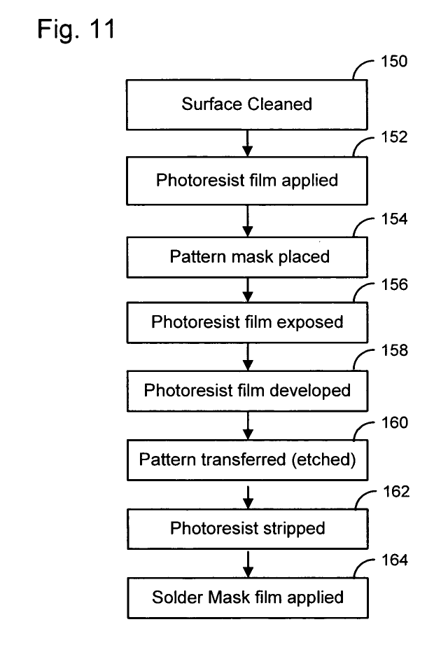

The layer 108 and/or layer 110 may be etched with a conductance pattern for communicating signals between one or more semiconductor die and an external device. One process for forming the conductance pattern on the substrate 100 is explained with reference to the flowchart of FIG. 11. The surfaces of conductive layers 108 and 110 are cleaned in step 150. A photoresist film is then applied over the surfaces of layers 108 and 110 in step 152. A pattern mask containing the outline of the electrical conductance pattern may then be placed over the photoresist film in step 154. The photoresist film is exposed (step 156) and developed (step 158) to remove the photoresist from areas on the conductive layers that are to be etched. The exposed areas are next etched away using an etchant such as ferric chloride in step 160 to define the conductance patterns on the core. Next, the photoresist is removed in step 162, and the solder mask layer is applied in step 164. Other known methods for forming the conductance pattern on substrate 100 are contemplated.

Once patterned, the top and bottom conductive layers 108, 110 may be laminated with a solder mask 112, and, in embodiments where substrate 100 is used for example as an LGA package, one or more gold layers may be formed on portions of the bottom conductive layer 110 to define contact fingers 114 as is known in the art for communications with external devices.

As explained in the Background of the Invention section, owing to the unevenness of the upper surface of the solder mask, air bubbles form on the substrate between the solder mask and a die attach adhesive for attaching a semiconductor die (explained hereinafter). These air bubbles can delaminate and/or crack the die, for example during the encapsulation process where the trapped air bubbles conventionally expand with the increase in temperature.

Therefore, according to embodiments of the present invention, the layer of solder mask 112 which receives the semiconductor die may be patterned with one or more canals 120 as shown in FIGS. 2 and 3. Conventionally, the solder mask has been applied to the surface of the substrate to prevent solder from sticking to any metallization except where openings are patterned into the solder mask, such as openings 122. There may be less or many more openings 122 than shown in FIG. 2. In accordance with the present invention, canals 120 are also patterned into the solder mask. The one or more canals are patterns that provide a passageway for air bubbles to be expelled from beneath the semiconductor die, as explained in greater detail hereinafter.

The canals 120 may be patterned into the solder mask by a variety of known processes, at the same time and manner as openings 122. Canals 120 may be formed at a different time and/or in a different manner than openings 122 in alternative embodiments. An example of the steps which may be used to apply solder mask 112 to substrate 100 is disclosed in U.S. Pat. No. 6,825,569, to Jiang, et al., entitled, “BGA Package Having Substrate with Patterned Solder Mask Defining Open Die Attach Area,” which patent is hereby incorporated by reference in its entirety. In general, in one embodiment, the solder mask may comprise a photoimageable, dielectric material that can be blanket deposited on layers 108 and 110 as a wet or dry, positive or negative tone resist film. One suitable resist film is commercially available from Taiyo America, Inc., Carson City, Nev. under the trademark “PSR-4000.” The PSR-4000 resist can be mixed with an epoxy such as epoxy “720” manufactured by Ciba-Geigy (e.g., 80% PSR-4000 and 20% epoxy “720”). Another suitable resist is commercially available from Shipley, Co. under the trademark “XP-9500.” Other materials from which solder mask 112 may be formed are known.

The mask materials can be blanket deposited onto the substrate 100 using a suitable deposition process, such as by spraying the mask materials through a nozzle onto the substrate 100, or by moving the substrate 100 through a curtain coater conveyor having curtains of the mask materials. A representative thickness of the mask materials can be from about 1 mil to 4 mils.

Following blanket deposition of the mask materials, a prebaking step can be performed to partially harden the mask materials. For example, the mask materials can be prebaked at about 95° C. for about 15 minutes. Following prebaking, the mask materials can be exposed in a desired pattern using a suitable mask, and a conventional UV aligner. A representative UV dose can be about 165 mJ/cm². The mask includes the pattern for the one or more canals 120.

Following exposure of the mask materials, a developing step can be performed. The developing step can be performed using a suitable developing solution such as a 1 to 1.5 percent solution of sodium monohydrate (Na₂CO₃—H₂O), or potassium carbonate monohydrate (K₂CO—H₂O). Following the developing step, the mask materials can be rinsed, dried and cured. Curing can be performed by exposure to UV at a desired power (e.g., 3-5 J/cm²), or by heating to a desired temperature (e.g., 150-155° C.) for a desired time (e.g., one hour). Solder mask 112 may be formed with the one or more canals 120 by other known methods in alternative embodiments.

As shown in FIGS. 2 and 3, canals 120 may have a wavy, undulating shape. It has been determined that substrate surfaces below the semiconductor die that include etched lines that line up along the axes of the semiconductor die can increase the mechanical and/or thermal stresses on the die. The undulating shape of the one or more canals ensures that no length of the canals will align with the axes of the die. As explained hereinafter, the shape of the canals may vary in alternative embodiments. As indicated above, the depth of the canals may be the depth of the solder mask 112. i.e., 1 to 4 mils, though the thickness of the mask 112 and canals 120 may vary above or below that in alternative embodiments. The width of canals 120 may be between 1 to 4 mils, but the width may also vary above or below that in alternative embodiments. It will be appreciated that the cross-sectional area of the canals 120 need only be large enough to allow air passage therethrough.

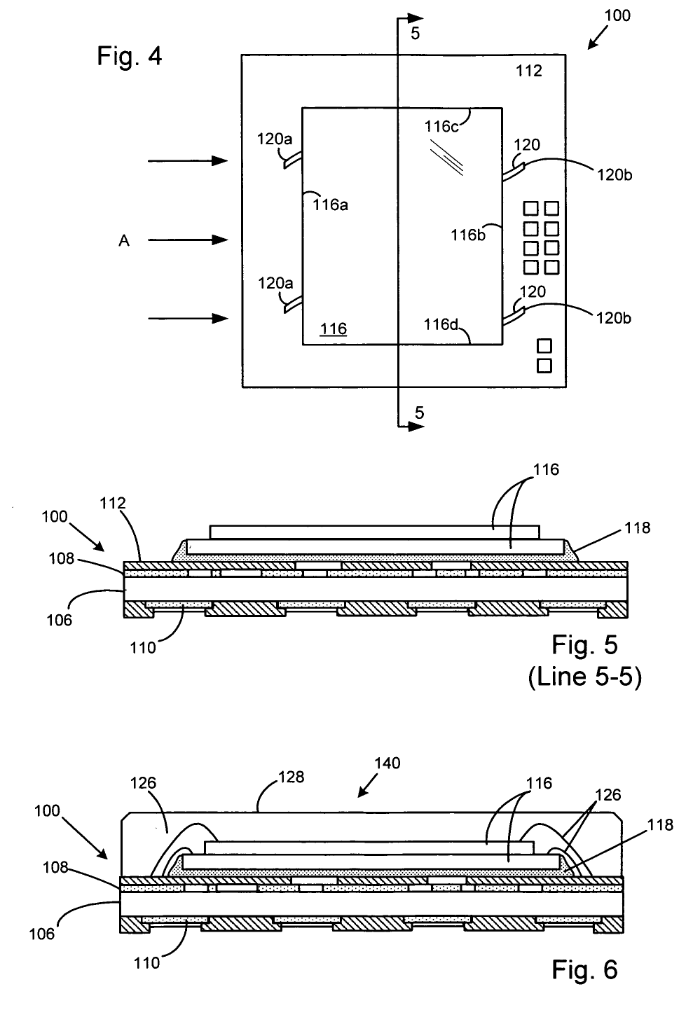

FIGS. 4 and 5 are top and cross-sectional views of the substrate 100 described above, further having two stacked semiconductor die 116 mounted on the solder mask layer 112 on the top surface of the substrate. The die 116 may be mounted on a designated section of the substrate, which designated section may simply be an area on the substrate on which the die is mounted via a die attach film. Although not critical to the present invention, the substrate 100 may alternatively support a single dice, or between 3 and 8 or more die stacked in an SiP, MCM or other type of arrangement. The one or more die may have thicknesses ranging between 8 mils to 20 mils, but the one or more die may be thinner than 8 mils and thicker than 20 mils in alternative embodiments. While not critical to the present invention, the one or more die 116 may be a flash memory chip (NOR/NAND), SRAM or DDT, and/or a controller chip such as an ASIC. Other silicon chips are contemplated.

The one or more die 116 may be mounted on the top surface of the substrate 100 in a known adhesive or eutectic die bond process, using a known die attach film 118. The die attach film may be for example any of various polymer adhesives. Such die attach compounds are manufactured for example by Semiconductor Packaging Materials, Inc. of Armonk, N.Y.

Referring now to FIG. 6, the one or more die 116 may be electrically connected to conductive layers 108, 110 of the substrate 100 by wire bonds 126 in a known wire bond process. Thereafter, the substrate and die may be encased within a molding compound 128 in a known encapsulation process to form a finished semiconductor die package 140. Molding compound 128 may be an epoxy such as for example available from Sumitomo Corp. and Nitto Denko Corp., both having headquarters in Japan. Other molding compounds from other manufacturers are contemplated. The molding compound may be applied according to various processes, including by transfer molding or injection molding techniques, to encapsulate the substrate 100 and semiconductor die 116.

The mold compound is introduced over the substrate 100 and semiconductor die 116 from the direction indicated by arrows A in FIG. 4. Advancing in this direction, the molding compound encounters an edge 116a of the die first. Die 116 includes a second edge 116b opposite edge 116a. In embodiments, the one or more canals 120 may be generally oriented along the direction of flow of the molding compound between die edges 116a and 116b. Thus, as the compound advances over the substrate and die, any air bubbles that may have formed due to gaps below the adhesive film 118 may escape from beneath the die 116 through the one or more canals 120, and exit the canal at a canal end 120b extending beyond edge 1116b.

Canal 120 also has an end 120a, which as shown in FIG. 4, extends on substrate 100 out beyond the edge 116a of the die 116. It is understood that end 120a need not extend out beyond the edge 116a of die 116, and may instead lie beneath the die 116, in alternative embodiments. Moreover, instead of end 120b extending out beyond edge 116b, it is further contemplated that end 120b may extend out of the top or bottom edge of the die (edges 116c or 116d) near edge 116b, in further embodiments. As explained hereinafter, the canal may be formed of different branches which may converge together or diverge apart. In such an embodiment, the diverging branches may extend out beyond one or more of edges 116b, 116c and 116d.

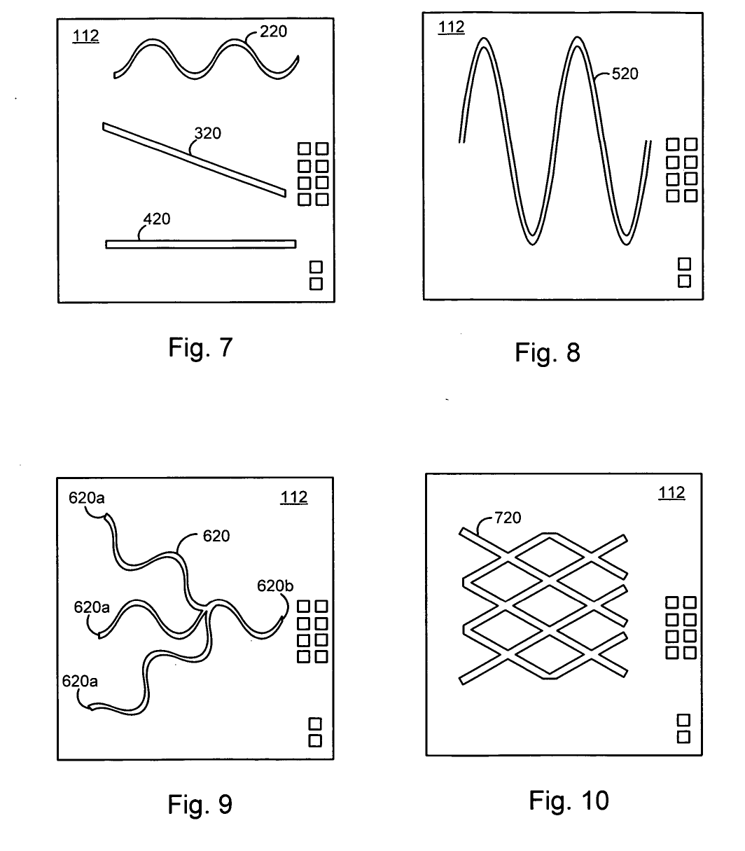

As indicated above, a number of canals 120 may be etched into the solder mask 112, such as for example between 1 and 5 such canals, though the number may be higher than that in alternative embodiments. Additionally, the canal 120 may take on a variety of different configurations and accomplish the venting of air bubbles from beneath the semiconductor die 116. Some of these alternative configurations are shown in FIGS. 7 through 10. FIG. 7 shows a canal 220 having a tighter undulation frequency than the canal 120 of FIG. 2. It is understood that, over its length, canal 220 may have a wide variety of periods (peaks/valleys) in alternative embodiments. Canal 320 is formed with straight edged sections, provided on a slant relative to the die 116. Canal 320 may slant upward or downward. It was indicated above that there may be disadvantages to a canal aligned along an axis of the die 116. However, such a canal is still possible in alternative embodiments, as shown by canal 420 in FIG. 7. Solder mask 112 may have one or more of the canals 120, 220, 320 and/or 420 shown in FIGS. 2 and 7.

The amplitude of the canals (i.e., distance between the peaks/valleys) may vary in alternative embodiments. Canal 520 shown in FIG. 8 can have peaks and valleys that extend near, to or beyond the upper and lower edges of the semiconductor die 116 mounted thereon.

In a further alternative embodiment shown in FIG. 9, a canal 620 may have a plurality of branches, one or more of which come together. The branches may come together or branch apart from the first end(s) 620a to the second end(s) 620b. The branches may be formed of straight and/or undulating sections. A further embodiment is shown in FIG. 10, where a canal 720 includes a criss-cross pattern of branches. The branches may be straight as shown, or undulating.

In accordance with embodiments of the present invention, as air bubbles develop and/or expand, for example during the molding process, the canals allow the air bubbles to be expelled from the beneath the semiconductor die. Thus, the problem of delamination and/or die cracking due to the formation and expansion of trapped air bubbles may be significantly reduced or avoided altogether. Each of the above-described canals is an example of a passageway for air bubbles to be expelled from beneath the semiconductor die. Those of skill in the art will appreciate that other passageway configurations are possible. The total area of the canal(s) beneath the semiconductor may vary in alternative embodiments.

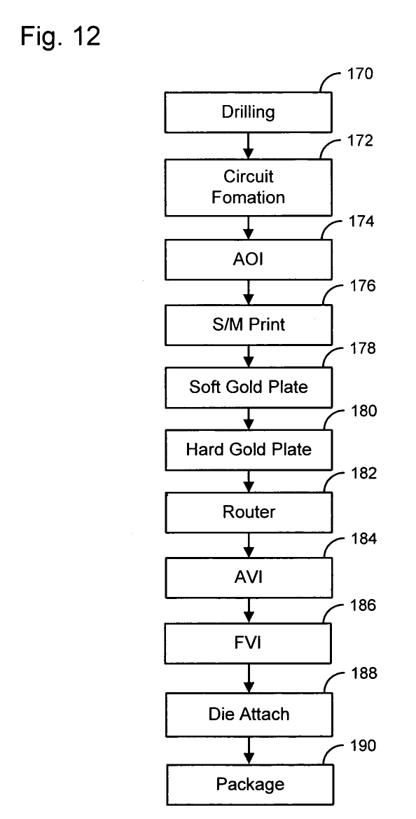

A process for forming the finished die package 140 is explained with reference to the flowchart of FIG. 12. The substrate 100 starts out as a large panel which is separated into individual substrates after fabrication. In a step 170, the panel is drilled to provide reference holes off of which the position of the respective substrates is defined. The conductance pattern may then be formed on the respective surfaces of the panel in step 172 as explained above. The patterned panel is then inspected in an automatic optical inspection (AOI) in step 174. Once inspected, the solder mask is applied to the panel in step 176, including the canals as described above.

In embodiments where package 140 is for example an LGA package, after the solder mask is applied, the contact fingers for external connection are completed. A soft gold layer is applied over certain exposed surfaces of the conductive layer on the bottom surface of the substrate, as for example by thin film deposition, in step 178. As the contact fingers are subject to wear by contact with external electrical connections, a hard layer of gold may be applied, as for example by electrical plating, in step 180. It is understood that a single layer of gold may be applied in alternative embodiments. A router then separates the panel into individual substrates in step 182. The individual substrates are then inspected and tested in an automated step (step 184) and in a final visual inspection (step 186) to check electrical operation, and for contamination, scratches and discoloration. The substrates that pass inspection are then sent through the die attach process in step 188, and the substrate and die are then packaged in step 190 in a known injection mold process to form a JEDEC standard (or other) package. It is understood that the die package 140 including canals as described above may be formed by other processes in alternative embodiments.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

We claim:

1. A substrate for a semiconductor die, the substrate comprising:
a solder mask formed on a surface of the substrate, the solder mask including a pattern formed in the solder mask, the pattern defining a passageway for air bubbles to travel across at least a portion of the surface of the substrate.

2. A substrate as recited in claim 1, the substrate further comprising:
a core; and
conductance traces formed on the core, the solder mask being formed on the core and/or conductance traces.

3. A substrate as recited in claim 1, the pattern comprising a canal patterned into the solder mask.

4. A substrate as recited in claim 1, the pattern comprising undulations patterned into the solder mask.

5. A substrate as recited in claim 1, the pattern comprising straight sections patterned into the solder mask.

6. A substrate as recited in claim 1, the pattern comprising branches patterned into the solder mask, the branches converging together across a surface of the solder mask.

7. A substrate as recited in claim 1, the pattern comprising criss-crossed sections patterned into the solder mask.

8. A substrate as recited in claim 1, the pattern including first and second ends, at least one of the first and second ends patterned into the solder mask at a position that is outside of a position on the substrate designated to receive the semiconductor die.

9. A substrate for supporting a semiconductor die on a designated section of the substrate, the substrate comprising:
a solder mask formed on a surface of the substrate, the solder mask including a pattern formed in the solder mask, the pattern defining a passageway for air bubbles to travel, the passageway having a portion passing along the surface of the substrate and through at least part of the designated section of the substrate, and the passageway having at least one end located on the surface of the substrate outside of the designated section of the substrate.

10. A substrate as recited in claim 9, the substrate further comprising:
a core; and
conductance traces formed on the core, the solder mask being formed on the core and/or conductance traces.

11. A substrate as recited in claim 9, the pattern comprising a canal patterned into the solder mask.

12. A substrate as recited in claim 9, the pattern comprising undulations patterned into the solder mask.

13. A substrate as recited in claim 9, the pattern comprising straight sections patterned into the solder mask.

14. A semiconductor package including a substrate and a semiconductor die mounted to the substrate, the semiconductor package comprising:
a solder mask formed on a surface of the substrate, the solder mask including a pattern formed in the solder mask, the pattern defining a passageway allowing air bubbles to travel from beneath the semiconductor die, the passageway having a portion located beneath the semiconductor die, and the passageway having at least one end located on the surface of the substrate beyond an outer edge of the semiconductor die.

15. A semiconductor package as recited in claim 14, further comprising:
a core of the substrate;
a conductance pattern formed on the core;
a film for affixing the semiconductor die to the substrate; and
a molding compound for encapsulating the substrate and semiconductor die.

16. A semiconductor package as recited in claim 14, the pattern comprising a canal patterned into the solder mask.

17. A semiconductor package as recited in claim 14, the pattern comprising undulations patterned into the solder mask.

18. A semiconductor package as recited in claim 14, the solder mask having a thickness of between 1 mil and 4 mils, and the pattern formed in the solder mask having a width of between 1 mil and 4 mils.

19. A semiconductor package including a substrate and a semiconductor die mounted to the substrate, the semiconductor die having first and second opposed edges, and third and fourth opposed edges extending between the first and second opposed edges, the semiconductor package comprising:
a solder mask formed on a surface of the substrate;
a molding compound encapsulating at least a portion of the substrate and semiconductor die, the molding compound flowing over the semiconductor die during an encapsulation process generally in a direction from the first edge of the semiconductor die to the second edge of the semiconductor die;
a pattern formed in the solder mask, the pattern defining a passageway beneath the semiconductor die for air bubbles to travel from beneath the semiconductor die, the passageway having a first end extending out from beneath the second edge of the semiconductor die.

20. A semiconductor package as recited in claim 19, the pattern oriented in a direction generally in the direction of flow of the molding compound.

21. A semiconductor package as recited in claim 19, the passageway having a second end opposite the first end, the second end located adjacent the first edge of the semiconductor die.

22. A semiconductor package as recited in claim 19, the pattern comprising undulations patterned into the solder mask, the undulations including at least one peak extending toward the third edge of the semiconductor die beneath the semiconductor die, and at least one valley extending toward the fourth edge of the semiconductor die beneath the semiconductor die.

23. A method of preventing air bubbles from getting trapped beneath a semiconductor die during fabrication of a semiconductor package, the package including a substrate for supporting the semiconductor die, comprising the step of:
(a) defining a passageway beneath the semiconductor die through which air bubbles may travel out from beneath the semiconductor die during the fabrication of the semiconductor package.

24. A method as recited in claim 23, said step (a) comprising the step of forming the passageway within a solder mask applied to a surface of the substrate.

25. A method as recited in claim 23, said step (a) comprising the step of forming the passageway with an end extending out beyond an edge of the semiconductor die, the edge being opposite an edge that is generally the first edge of the semiconductor to be encapsulated with molding compound during an encapsulation process for the semiconductor package.
